(19) United States
(12) Patent Application Publication
(10) Pub. No.: US 2022/0330437 A1
(43) Pub. Date: Oct. 13, 2022

(54) Method for manufacturing multi-layer flexible circuit board and article thereof

(71) Applicant: LongKai LI, Chongqing (CN)

(72) Inventor: LongKai LI, Chongqing (CN)

(21) Appl. No.: 17/753,111

(22) PCT Filed: Oct. 23, 2019
(86) PCT No.: PCT/CN2019/112798

§ 371 Date: Feb. 18, 2022

(30) Foreign Application Priority Data
Aug. 23, 2019 (CN) 201910784378.8

(51) Int. Cl. H05K 3/46; H05K 1/02

(52) U.S. Cl. CPC H05K 3/4611; H05K 1/028; H05K 1/0216; H05K 2203/1105

(57) ABSTRACT

The present invention discloses a method for manufacturing a multi-layer flexible circuit board, comprising the steps of: (1) manufacturing a double-sided FPC flexible board; (2) manufacturing a novel material layer structure; (3) hot pressing at least one group of upeer novel material layer structures on the circuits on the upper and/or lower surfaces of the double-sided FPC flexible board; forming a protective layer on the circuits of an outermost novel material layer structure and/or on exposed circuits of the double-sided FPC flexible board so as to obtain a multi-layer flexible circuit board. The present invention also discloses a multi-layer flexible circuit board manufactured by performing the above-mentioned method. The manufacturing process of the present invention is simplified, convenient and efficient; the multi-layer flexible circuit board not only greatly simplifies the novel material layer structure and reduces the overall thickness, but also has the function of high-speed transmission of high-frequency signals, especially suitable for new 5G technology products. It can protect and resist the migration of copper ions when it is energized between circuits so as to ensure the safety and normal operation of circuits.

### TECHNICAL FIELD

The present invention relates to the field of circuit boards, and more particularly to a method for manufacturing a multi-layer flexible circuit board and an article thereof.

### BACKGROUND ART

At present, the communication frequency is overall high-frequency from the communication network to the terminal application. High-speed and large-capacity applications emerge endlessly. As wireless networks transition from 4G to 5G in recent years, network frequencies continue to rise. According to the 5G development roadmap shown in the relevant data, the future communication frequency will be promoted in two stages. The first phase aims to increase the communication frequency to 6 GHz by 2020, and the second phase to further increase it to 30-60 GHz by 2020. In the market application, the signal frequency of terminal antennas such as smart phones is increasing. There are more and more high-frequency applications, which acquire more and more demand for high-speed and large-capacity. To adapt to the current trend of high-frequency and high speed from wireless networks to terminal applications, soft boards, as antennas and transmission lines in terminal devices, will also be subject to technological upgrading.

The conventional soft board has a multi-layer structure composed of a copper foil, an insulating substrate, a cover layer and the like, with the copper foil as a conductor circuit material, a PI film as a circuit insulating substrate, and a PI film and an epoxy adhesive as a cover layer for protecting and isolating a circuit, which are processed into a PI soft board by a certain process. Since the properties of the insulating substrate determine the final physical and electrical properties of the soft board, the soft board needs to use substrates with various performance characteristics in order to adapt to different application scenarios and functions. Polyimide (PI) is the most widely used soft board substrate at present. However, due to the larger dielectric constant and loss factor, higher moisture absorption and poor reliability of PI substrate, the high-frequency transmission loss of PI soft board is serious and its structural characteristics are poor, which cannot adapt to the current high-frequency and high-speed trend. Therefore, with the emergence of new 5G technology products, the signal transmission frequency and speed of existing circuit boards have been difficult to meet the requirements of 5G technology products.

Meanwhile, there are many problems in the traditional manufacturing process of multi-layer flexible circuit board, such as more process flows, more complex manufacturing process, and higher power consumption and signal transmission loss in circuit board performance.

Also, the copper ion migration phenomenon will usually occur between the lines when the circuit board in the precise line is powered on. During the use of the device, there will be a risk that the circuit will burn and explode due to the conductive collision between the lines, resulting in that the lines on the circuit board cannot work safely and normally.

### SUMMARY OF THE INVENTION

In view of the above-mentioned deficiencies, the object of the present invention is to provide a method for manufacturing a multi-layer flexible circuit board and an article thereof, wherein the manufacturing process of the circuit board is simplified and more convenient to manufacturing, and the production and processing efficiency is improved; the multi-layer flexible circuit board not only greatly simplifies the novel material layer structure and reduces the overall thickness of the circuit board, but also has high-frequency characteristics, i. e. high-speed transmission of high-frequency signals, which can adapt to the current high-frequency and high-speed trends from wireless network to terminal applications, especially for new 5G technology products. Meanwhile, it can protect and resist the migration of copper ions when it is energized between circuits so as to ensure the safety and normal operation of circuits.

The technical solution adopted by the invention for achieving the above purpose is as follows.

A method for manufacturing a multi-layer flexible circuit board is characterized by comprising the steps of:

(1) manufacturing a double-sided FPC flexible board: applying a copper layer on upper and lower surfaces of a base film respectively, and forming a circuit on the copper layer to obtain a double-sided FPC flexible board;

(2) manufacturing at least one group of novel material layer structures;

(2.1) applying a copper layer on one surface of the film to form a single-sided board;

(2.2) applying a semi-cured high-frequency material layer on the other surface of the film of the single-sided board to obtain at least one group of novel material layer structures;

(3) thermoforming: hot-pressing at least one group of novel material layer structures on the circuits of the upper surface and/or the lower surface of the double-sided FPC flexible board; in the hot-pressing process, firstly, gradually increasing the hot-pressing temperature from 50° C.-100° C. to 380° C.-400° C.. for 80 min -120 min; then, maintaining the hot-pressing temperature of 380° C.-400° C.. for 60 min -90 min; finally, gradually decreasing the hot-pressing temperature from 380° C.-400° C.. to 50° C.-100° C. for 30-60 min; wherein the hot pressing pressure is 400 psi -500 psi during the whole process; after hot-pressing, the semi-cured high-frequency material layer on the novel material layer structure is integrated with the circuits on the double-sided FPC flexible board; in this step, after each previous group of the novel material layer structures is hot pressed, forming a circuit on the copper layer of the novel material layer structure; finally, a protective layer is formed on the circuits of an outermost novel material layer structure and/or on exposed circuits of the double-sided FPC flexible board so as to obtain a multi-layer flexible circuit board;

wherein the step (1) has no sequential order with the step (2).

As a further improvement of the invention, the step (2.2) specifically comprises the steps of:

(2.2.1) placing the single-sided board on a coater, and coating the film of the single-sided board with a layer of a synthetic liquid high-frequency material;

(2.2.2) delivering the single-sided board coated with the synthetic liquid high-frequency material into a tunnel oven, and successively passing it through a first-stage heating and baking zone, a second-stage heating and baking zone, a third-stage heating and baking zone, a fourth-stage heating and baking zone, a fifth-stage heating and baking zone and a sixth-stage heating and baking zone in the tunnel oven at a speed of 0.5-20 m/s for stepwise baking, wherein the synthetic liquid high-frequency material on the single-sided board becomes a semi-cured high-frequency material layer; the temperature range of the first-stage heating and baking zone is 60° C.-100° C.; the temperature range of the second-stage heating and baking zone is 100° C.-200° C.; the temperature range of the third-stage heating and baking zone is 200° C.-300° C.; the temperature range of the fourth-stage heating and baking zone is 300° C.-400° C.; the temperature range of the fifth-stage heating and baking zone is 400° C.-500° C.; the temperature range of the sixth-stage heating and baking zone is 60° C.-100° C.; and the length of each stage heating and baking zone is 2-6 m.

As a further improvement of the present invention, in the step (1), the base film is any one of a PI film, an MPI film, an LCP film, a TFP film, and a PTFE film; and in the step (2.1), the film is any one of a PI film, an MPI film, an LCP film, a TFP film and a PTFE film.

As a further improvement of the present invention, in the step (2.2), the semi-cured high-frequency material layer is an MPI film, an LCP film, a TFP film, a PTFE film, an LDK high-frequency functional adhesive, or a mixture of the LDK high-frequency functional adhesive with a copper ion migration resistant adhesive.

As a further improvement of the present invention, the LDK high-frequency functional adhesive is obtained by adding Teflon or LCP material to an AD adhesive; and the copper ion migration resistant paste is obtained by adding a copper ion scavenger to the AD adhesive, followed by high purification.

As a further improvement of the present invention, in the step (2.2), a colored filler is added to at least one of the semi-cured high-frequency material layer and the film.

A multi-layer flexible circuit board prepared by performing the above-mentioned method is characterized by comprising a double-sided FPC flexible board, several groups of upper novel material layer structures laminated on the upper surface of the double-sided FPC flexible board, and several groups of lower novel material layer structures laminated on the lower surface of the double-sided FPC flexible board, wherein the double-sided FPC flexible board comprises a base film, a first upper circuit layer arranged on the upper surface of the base film, and a first lower circuit layer arranged on the lower surface of the base film; the upper novel material layer structure comprises an upper semi-cured high-frequency material layer arranged on the upper surface of the first upper circuit layer, an upper film arranged on the upper surface of the upper semi-cured high-frequency material layer, and a second upper circuit layer arranged on the upper surface of the upper film; and the lower novel material layer structure comprises a lower semi-cured high-frequency material layer arranged on the lower surface of the first lower circuit layer, a lower film arranged on the lower surface of the lower semi-cured high-frequency material layer, and a second lower circuit layer arranged on the lower surface of the lower film.

As a further improvement of the present invention, the base film is any one of a PI film, an MPI film, an LCP film, a TFP film and a PTFE film; the upper film is any one of a PI film, an MPI film, an LCP film, a TFP film and a PTFE film; and the lower film is any one of a PI film, an MPI film, an LCP film, a TFP film and a PTFE film.

As a further improvement of the present invention, the upper semi-cured high-frequency material layer is an MPI film, an LCP film, a TFP film, a PTFE film, an LDK high-frequency functional adhesive, or a mixture of the LDK high-frequency functional adhesive with a copper ion migration resistant adhesive; and the lower semi-cured high-frequency material layer is an MPI film, an LCP film, a TFP film, a PTFE film, an LDK high-frequency functional adhesive, or a mixture of the LDK high-frequency functional adhesive with a copper ion migration resistant adhesive.

As a further improvement of the present invention, at least one of the upper half-cured high-frequency material layer and the upper film is a colored layer; and at least one of the lower half-cured high-frequency material layer and the lower film is a colored layer.

As a further improvement of the present invention, an upper protective layer is provided on the upper surface of the second upper circuit layer of the outermost novel material layer structure above the double-sided FPC flexible board; and a lower protective layer is provided on the lower surface of the second lower circuit layer of the outermost lower novel material layer structure below the double-sided FPC flexible board.

As a further improvement of the invention, the upper protective layer is a solder mask ink layer or a combination of an adhesive layer and a PI film; and the lower protective layer is a solder mask ink layer or a combination of an adhesive layer and a PI film.

The invention has the following beneficial effects.

(1) A multi-layer flexible circuit board is manufactured by firstly manufacturing a double-sided FPC flexible board and several groups of novel material layer structures, and then hot-pressing the several groups of novel material layer structures on the double-sided FPC flexible board. According to specific requirements, the multi-layer flexible circuit board with the required number of layers can be formed by hot-pressing. The circuit board manufacturing process is simplified and more convenient to manufacture, and the circuit board manufacturing speed is accelerated; and the production processing efficiency is improved, and the production cost is reduced.

(2) MPI film, LCP film, TFP film or PTFE film, instead of the traditional PI thin film, is used as the base material of the circuit formed on the double-sided FPC flexible board and the novel material layer structure, which can not only improve the stability and dimensional stability of the overall performance of the circuit board, but also have high-frequency characteristics. It can transmit high-frequency signals, speed up the transmission speed of high-frequency signals, and achieve high-speed transmission of high-frequency signals, with low power consumption and high-frequency signal transmission loss, improving the signal transmission performance of the circuit board. It can adapt to the current high-frequency and high-speed trend from wireless networks to terminal applications, especially for new 5G technology products.

(3) A semi-cured high-frequency material layer is used to replace the traditional semi-cured AD adhesive; and the semi-cured high-frequency material layer can specifically be an MPI film, an LCP film, a TFP film, a PTFE film or an LDK high-frequency functional adhesive, so that the prepared novel material layer structure has a high-frequency characteristic and can transmit high-frequency signals at a high speed, i. e. having the function of improving the signal transmission frequency and resisting magnetic interference. Then the multi-layer flexible circuit board prepared by hot pressing the several groups of novel material layer structure on the double-sided FPC flexible board has high-frequency characteristics, can transmit high-frequency signals, and speed up the transmission speed of high-frequency signals to achieve high-speed transmission of high-frequency signals with low power consumption and high-frequency signal transmission loss, further improving the signal transmission performance of the circuit board. It can adapt to the current high-frequency and high-speed trend from wireless network to terminal applications, especially for new 5G technology products.

(4) A semi-cured high-frequency material layer is used to replace the traditional semi-cured AD adhesive; the semi-cured high-frequency material layer can specifically be a mixture of an LDK high-frequency functional adhesive and a copper ion migration resistant adhesive; that is to say, the semi-cured high-frequency material layer not only has the property of transmitting high-frequency signals, but also has the function of anti-copper ion migration, so that the manufactured novel material layer structure not only has the high-frequency property and can transmit a high-frequency signals at a high speed, but also has the function of anti-copper ion migration. Then, the multi-layer flexible circuit board prepared by hot-pressing the several groups of novel material layer structure onto the double-sided FPC flexible board can effectively ensure that the circuit board can work safely and effectively in the working state; and no migration of copper ions will occur between the circuits when the circuit board is powered on. During the use of the device, the migration of copper ions between the circuits is prevented, so as to prevent the occurrence of circuit short circuit, combustion and fire caused by circuit conduction, battery explosion, and functional failure and other hazards, so that the circuit plays a good protective role.

(5) Structurally, combining an upper novel material layer structure and a lower novel material layer structure with a special layer structure respectively and successively laminating the same, the structural design of a multi-layer flexible circuit board can be achieved for 4-layer, 6-layer, 8-layer, or more-layer structural designs, so as to meet more requirements; meanwhile, compared with the traditional four-layer double-sided flexible circuit board, two adhesive layers and two film layers are reduced only for the four-layer double-sided flexible circuit board with the improved upper novel material layer structure and upper novel material layer structure, and the novel material layer structure of the product is greatly simplified; thus, the overall thickness of the multi-layer flexible circuit board is reduced, the overall product material cost is reduced, and the assembly space is optimized; and the product signal transmission speed is improved, the power consumption is reduced, and the moisture and heat resistance of the product is improved, so that the overall performance of the product is improved.

The above is an overview of the technical scheme of the invention. The following is a further explanation of the invention in combination with the attached drawings and specific implementations.

### BRIEF DESCRIPTION OF THE DRAWINGS

FIG. 1 is an exploded view of a four-layer double-sided flexible circuit board according to the present invention;

FIG. 2 is an overall sectional view of a four-layer double-sided flexible circuit board according to the present invention;

FIG. 3 is another overall sectional view of a four-layer double-sided flexible circuit board according to the present invention;

FIG. 4 is an overall sectional view of a six-layer double-sided flexible circuit board according to the present invention;

FIG. 5 is another overall sectional view of a six-layer double-sided flexible circuit board according to the present invention;

FIG. 6 is an overall cross-sectional view of a three-layer double-sided flexible circuit board according to the present invention.

### DETAILED DESCRIPTION

In order to further explain the technical means and effects of the present invention for achieving the intended purpose, the following detailed description of the embodiments of the present invention will be made with reference to the accompanying drawings and preferred embodiments.

Embodiments of the present invention provide a method for manufacturing a multi-layer flexible circuit board, comprising the steps of:

(1) manufacturing a double-sided FPC flexible board: applying a copper layer on upper and lower surfaces of a base film respectively, and forming a circuit on the copper layer to obtain a double-sided FPC flexible board;

(2) manufacturing at least one group of novel material layer structures;

(2.1) applying a copper layer on one surface of the film to form a single-sided board;

(2.2) applying a semi-cured high frequency material layer on the other surface of the film of the single-sided board to obtain at least one group of novel material layer structures;

(3) thermoforming: hot-pressing at least one group of novel material layer structures on the circuits of the upper surface and/or the lower surface of the double-sided FPC flexible board; in the hot-pressing process, firstly, gradually increasing the hot-pressing temperature from 50° C.-100° C. to 380° C.-400° C. for 80 min -120 min; then, maintaining the hot-pressing temperature of 380° C.-400° C. for 60 min -90 min; finally, gradually decreasing the hot-pressing temperature from 380° C.-400° C. to 50° C.-100° C. for 30-60 min; wherein the hot pressing pressure is 400 psi -500 psi during the whole process; after hot-pressing, the semi-cured high-frequency material layer on the novel material layer structure is integrated with the circuits on the double-sided FPC flexible board; in this step, after each previous group of the novel material layer structures is hot pressed, forming a circuit on the copper layer of the novel material layer structure; finally, a protective layer is formed on the circuits of an outermost novel material layer structure and/or on exposed circuits of the double-sided FPC flexible board so as to obtain a multi-layer flexible circuit board;

wherein the step (1) has no sequential order with the step (2).

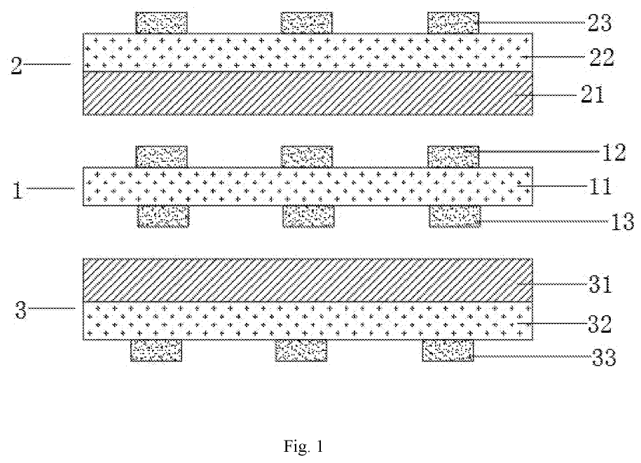

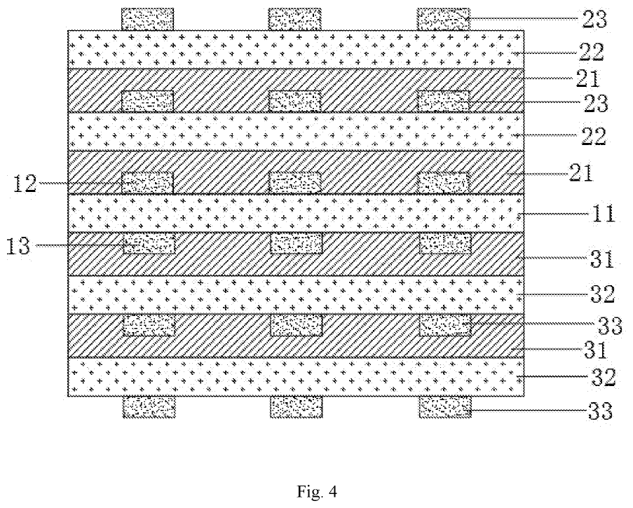

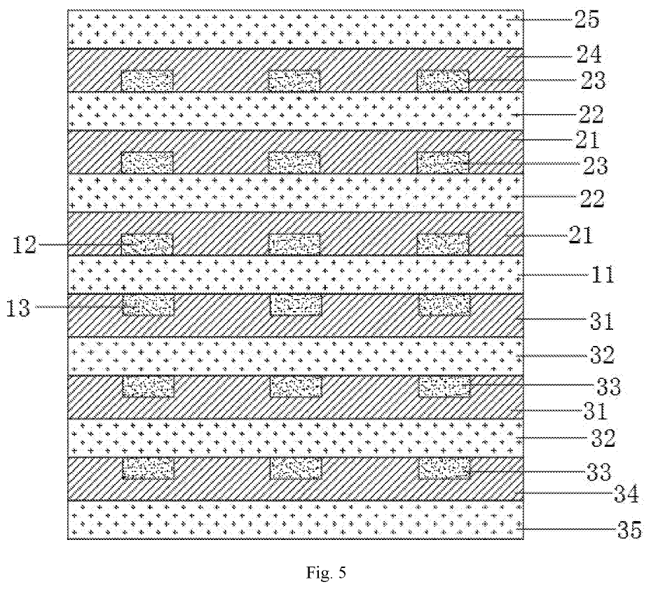

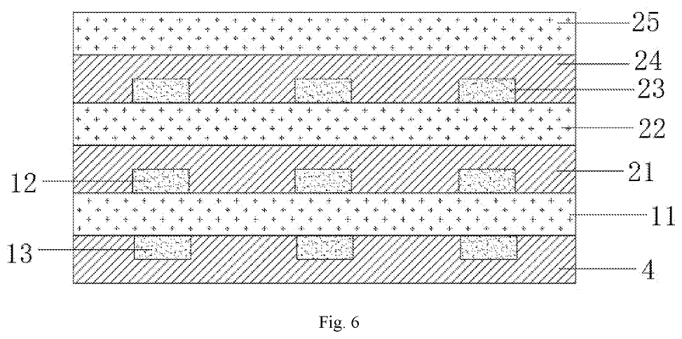

In this embodiment, a multi-layer flexible circuit board is manufactured by firstly preparing a double-sided FPC flexible board and several groups of novel material layer structures, and then hot-pressing the several groups of novel material layer structures on the double-sided FPC flexible board. According to specific requirements, the required number of layers of the multi-layer flexible circuit board can be formed by hot-pressing, and the circuit board manufacturing process is simplified and more convenient to manufacturing. As shown in FIGS. 1-3, a group of novel material layer structures are respectively hot-pressed on the upper and lower surfaces of a double-sided FPC flexible board to form a four-layer double-sided flexible circuit board. As shown in FIGS. 4 and 5, two groups of novel material layer structures are respectively hot-pressed on the upper and lower surfaces of a double-sided FPC flexible board to form a six-layer double-sided flexible circuit board. Of course, more groups of novel material layer structures can be respectively hot-pressed on the upper and lower surfaces of the double-sided FPC flexible board to form a multi-layer flexible circuit board. The novel material layer structure can also be hot-pressed on one of the upper surface and the lower surface of the double-sided FPC flexible board, with a protective layer formed on the circuit on the surface of the double-sided FPC flexible board without hot-pressing the novel material layer structure. As shown in FIG. 6, it is a three-layer double-sided flexible circuit board.

In this embodiment, the protective layer may be a solder mask ink layer, or a combination of an adhesive layer layer and a PI film to protect the circuit.

In the present embodiment, the step (2.2) specifically comprises the steps of:

(2.2.1) placing the single-sided board on a coater, and coating the film of the single-sided board with a layer of a synthetic liquid high-frequency material;

(2.2.2) delivering the single-sided board coated with the synthetic liquid high-frequency material into a tunnel oven, and successively passing it through a first-stage heating and baking zone, a second-stage heating and baking zone, a third-stage heating and baking zone, a fourth-stage heating and baking zone, a fifth-stage heating and baking zone and a sixth-stage heating and baking zone in the tunnel oven at a speed of 0.5-20 m/s for stepwise baking, wherein the synthetic liquid high-frequency material on the single-sided board becomes a semi-cured high-frequency material layer; the temperature range of the first-stage heating and baking zone is 60° C.-100° C.; the temperature range of the second-stage heating and baking zone is 100° C.-200° C.; the temperature range of the third-stage heating and baking zone is 200° C.-300° C.; the temperature range of the fourth-stage heating and baking zone is 300° C.-400° C.; the temperature range of the fifth-stage heating and baking zone is 400° C.-500° C.; the temperature range of the sixth-stage heating and baking zone is 60° C.-100° C.; and the length of each stage heating and baking zone is 2-6 m.

In the step (1), the base film is any one of a PI film, an MPI film, an LCP film, a TFP film, and a PTFE film; and in the step (2.1), the film is any one of a PI film, an MPI film, an LCP film, a TFP film and a PTFE film. Specifically, the PI film, MPI film, LCP film, TFP film and PTFE film include the characteristics and advantages respectively.

Pi film is polyimide film, which is a good film-like insulating material, and is prepared from pyromellitic dianhydride (PMDA) and diamino diphenyl ether (DDE) by polycondensation and casting in a strong polar solvent and then imidization. Pi film has excellent high and low temperature resistance, electrical insulation, adhesion, radiation resistance and dielectric resistance, and can be used for a long time in the temperature range of -269° C.-280° C., which can reach high temperature of 400° C. in a short time. The vitrification temperatures are 280° C. (Upilex R), 385° C. (Kapton) and above 500° C. (Upilex S), respectively. The tensile strength is 200 MPa at 20° C. and greater than 100 Ma at 200° C. It is particularly suitable as a substrate for flexible circuit boards.

MPI (Modified PI) is a modified polyimide, i. e. modified by a polyimide (PI) formulation. 1VIPI, because it is a non-crystalline material, has a wide operating temperature. It is easy to handle during the copper foil pressing at low temperature, has a surface capable of bonding with copper, and is inexpensive. Specifically, the fluoride formulation is improved, so that the MPI film can transmit a high-frequency signal of 10-15 GHz. Using MPI film as a substrate to form a circuit is particularly suitable for preparing a flexible circuit board for the purpose of high-speed, stable reception and transmission of information; and terminal applications include such as 5G mobile phones, high-frequency signal transmission fields, automatic driving, radar, cloud servers and smart homes.

With speed measurement, the technical indicators of MPI film include:

| Performance | | Test Value | | Standard |
|---|---|---|---|---|
| Peel strength (kgf/cm) | (A) | 0.84 | | ≤0.7 |
| Dielectric constant Dk | 10 GHz | 2.79 | | ≤3.0 |
| Loss factor Df | 10 GHz | 0.0049 | | ≤0.005 |
| Dimensional | Method B | MD: 0.03 TD: 0.02 | | ≤±0.15 |
| stability (%) | Method C | MD: 0.06 TD: 0.04 | | |
| Chemical | 10% HCl/ | 0.77 | reduction | ≤20% |
| resistance (%) | 10 min | | rate = 8.3% | |
| | 10% NaOH/ | 0.83 | reduction | |
| | 10 min | | rate = 1.2% | |
| | IPA/10 min | 0.76 | reduction | |
| | | | rate = 9.5% | |

| | | | |
|---|---|---|---|
| Flame retardancy | UL-94 V0 | Pass | UL-94 V0 |

It can be seen from the above that the MPI film has the following properties.

(1) Low Dk value, low Df value;

(2) Excellent heat aging resistance;

(3) Excellent dimensional stability;

(4) Excellent chemical resistance.

Therefore, using the MPI film as the substrate required for forming the circuit in this embodiment can not only improve the stability and dimensional stability of the overall performance of the circuit board, but also can transmit high-frequency signals, and accelerate the transmission speed of high-frequency signals to improve the signal transmission performance of the circuit board, so as to adapt to the current high-frequency and high-speed trend from wireless networks to terminal applications.

LCP, all known as Liquid Crystal Polymer, is a novel thermoplastic organic material that generally exhibit a liquid crystalline property in the molten state. LCP film is a liquid crystal polymer film. LCP film has the properties of high strength, high rigidity, high temperature resistance, thermal stability, bendability, dimensional stability, and good electrical insulation, etc., and has better water resistance than PI film. Therefore, it is a film-type material superior to the PI film. LCP film can achieve high-frequency and high-speed soft board with high reliability. LCP films have the following excellent electrical characteristics.

(1) A constant dielectric constant can be maintained in all radio frequency ranges up to 110 GHz with good consistency; and the specific value of dielectric constant Dk is 2.9.

(2) Tangent loss is very small, only 0.002, even only increased to 0.0045 at 110 GHz, which is very suitable for millimeter wave applications.

(3) The thermal expansion characteristic is very small. It can be used as an ideal high-frequency packaging material.

The use of LCP film as the substrate required for forming the circuit in this embodiment can not only improve the stability and dimensional stability of the overall performance of the circuit board, but also have less LCP film material medium loss and conductor loss due to the smoother overall LCP film; meanwhile, it has flexibility and sealing, can transmit high-frequency signals, and accelerate the transmission speed of high-frequency signals, which can improve the signal transmission performance of the circuit board and can adapt to the current high-frequency high-speed trend from wireless network to terminal applications.

Specifically, it can effectively improve the speed at which the circuit board transmits the command issued by the central area (chip) in the working state, and quickly transmit the command to each component, so that the device (such as mobile phone and communication base station device) can operate quickly without the phenomena of slowness or jam, and the communication process is smooth as a whole. Therefore, LCP film has a good prospect for high-frequency devices, especially for new 5G technology products.

Meanwhile, the LCP soft board made of LCP film as the substrate has better flexibility, which can further improve the space efficiency compared with PI soft board. Flexible electronics can be further thinned with a smaller bend radius. Therefore, the pursuit of flexibility is also a manifestation of miniaturization. According to the judgment of resistance change of more than 10%, under the same experimental conditions, LCP soft board can endure more bending times and smaller bending radius than traditional PI soft board, so that LCP soft board has better flexibility performance and product reliability. The excellent flexibility makes it possible to design the shape of LCP soft board freely so as to make full use of the narrow space in smart phones and further improve the efficiency of space utilization.

Therefore, a miniaturized high-frequency high-speed LCP soft board can be manufactured using an LCP film as a substrate.

TFP is a unique thermoplastic material with the following properties compared to conventional PI materials.

(1) Low dielectric constant: a low Dk value, the Dk value being specifically 2.55; while the Dk value of conventional PI is 3.2; therefore, the signal propagation speed is faster, the thickness is thinner, and the spacing is closer; and the power processing capacity is higher.

(2) Ultra-low material loss.

(3) Ultrahigh temperature performance, withstanding a high temperature of 300° C.

(4) The moisture absorption rate is relatively low.

Therefore, the use of the TFP film as the substrate required for forming the circuit in this embodiment can not only improve the stability and dimensional stability of the overall performance of the circuit board, but also can transmit high-frequency signals, and accelerate the transmission speed of high-frequency signals, and improve the signal transmission performance of the circuit board, so as to adapt to the current high-frequency and high-speed trend from wireless networks to terminal applications.

PTFE, polytetrafluoroethylene, is also named Teflon. Polytetrafluoro ethylene (PTFE) has excellent dielectric properties, chemical resistance, heat resistance and flame resistance, and has small dielectric constant and dielectric loss and small change in high-frequency range. The main performances are as follows.

1. Electrical performance

(1) Dielectric constant: 2.1;

(2) Dielectric loss: 5×10⁻⁴;

(3) Volume resistance: 1018Ω·cm;

2. Chemical performance: acid-alkali resistance, organic solvent resistance and oxidation resistance;

3. Thermal stability: long-term operation in the temperature range of −200° C.-260° C.;

4. Flame retardancy: UL94V-0;

5. Weather resistance: there is no significant loss of mechanical properties outdoors for more than 20 years.

Therefore, using the PTFE film as the substrate required for forming the circuit in this embodiment can not only improve the stability and dimensional stability of the overall performance of the circuit board, but also can transmit high-frequency signals, and accelerate the transmission speed of high-frequency signals and reduce power consumption and high-frequency signal transmission loss to improve the signal transmission performance of the circuit board, so as to adapt to the current high-frequency and high-speed trend from wireless networks to terminal applications, suitable for new 5G technology products.

The integration of 5G base station makes the demand of high-frequency copper clad laminate grow rapidly. As one of the mainstream high-frequency base materials of 5G high-frequency high-speed copper clad laminate, PTFE will meet the huge market growth in the 5G era.

It can be seen therefrom that using any one of the above-mentioned PI film, MPI film, LCP film, TFP film and PTFE film as the substrate required for forming a circuit in this embodiment is particularly suitable for a flexible circuit board. Especially, the MPI film, LCP film, TFP film and PTFE film can not only improve the overall performance of the flexible circuit board, but also have a high-frequency characteristic, which can greatly accelerate the transmission of high-frequency signals and achieve high-speed transmission of high-frequency signals, particularly suitable for novel 5G technology products.

Specifically, in the step (2.2), the semi-cured high-frequency material layer is an MPI film, an LCP film, a TFP film, a PTFE film, an LDK high-frequency functional adhesive, or a mixture of the LDK high-frequency functional adhesive with a copper ion migration resistant adhesive. It can be seen from the above that the MPI film, LCP film, TFP film and PTFE film are all high-frequency thin film materials which can accelerate the frequency and speed of signal transmission, transmit high-frequency signals and improve the signal transmission performance of the circuit board,which can not only improve the overall performance of the flexible circuit board, but also have high-frequency characteristics and can greatly accelerate the transmission of high-frequency signals and achieve high-speed transmission of high-frequency signals. They are particularly suitable for new 5G technology products.

However, with regard to the LDK high-frequency functional adhesive, the LDK high-frequency functional adhesive is obtained by adding a Teflon or LCP material into the AD adhesive; the LDK high-frequency functional adhesive can be realized by adding a chemical material such as Teflon or LCP to a conventional AD adhesive, and the molecular distribution therein is more compact and uniform, which does not consume energy, so that the LDK high-frequency functional adhesive has the functions of improving the signal transmission frequency and resisting magnetic interference, so as to improve the signal transmission performance of the circuit board. Specifically, in the step (2.2), it can effectively improve the speed at which the circuit board transmits the command issued by the central area (chip) in the working state, and quickly transmit the command to each component, so that the device (such as mobile phone and communication base station device) can operate rapidly without the phenomena of slowness and jam, and the whole communication process of new 5G technology products is smooth.

In the case of the copper ion migration resistant adhesive, it is obtained by adding a reagent such as a copper ion scavenger to the AD adhesive, followed by high purification. In particular, the liquid AD adhesive may be a conventional AD adhesive. Optionally, the copper ion scavenger can be an inorganic ion exchangers (for example, IXE-700F, IXE-750, etc.) which have the ability to capture copper ions, and can prevent the migration of copper ions between circuits. After adding the copper ion scavenger to the AD adhesive, the copper ion scavenger has no effect on the performance of the AD adhesive, but can improve the performance stability of the AD adhesive. The conventional AD adhesive contains epoxy resin, tackifier, plasticizer and various fillers; and after a high purification process, the purity of the epoxy resin component in the AD adhesive is improved, and the possibility of migration of copper ions between circuits from the AD adhesive is significantly reduced, achieving the purpose of resisting migration of copper ions. Specifically, the conventional AD adhesive has a certain gap between each two components, and copper ions can migrate through the gap; however, when the concentration of the epoxy resin purified from the conventional AD adhesive is increased, the concentration of other components is significantly reduced, and the gap existing between the epoxy resin and other components is greatly reduced, thereby reducing the gap available for copper ion migration, so as to achieve the purpose of resisting copper ion migration. Since the copper ion migration resistant adhesive has the anti-copper ion migration function of the low-particle material, it can effectively ensure that the circuit can work safely and effectively in the working state, and there will be no ion migration phenomenon between the circuits, so as to prevent the conducting collision between the circuits during the use of the device, resulting in short circuit and combustion and explosion hazards, so that the circuit plays a good safeguard and protection role.

When the semi-cured high-frequency material layer is a mixture of an LDK high-frequency functional adhesive and a copper ion migration resistant adhesive, it is sufficient to mix the LDK high-frequency functional adhesive and the copper ion migration resistant adhesive, so that the semi-cured high-frequency material layer has both high-speed transmission high-frequency signals and copper ion migration resistant properties.

In the step (2.2), a colored filler is added to at least one of the semi-cured high-frequency material layer and the film. Specifically, the colored filler can be a carbide or other colored filler. The semi-cured high-frequency material layer (specifically, it can be an MPI film, an LCP film, a TFP film, a PTFE film, an LDK high-frequency functional adhesive, or a mixture of the LDK high-frequency functional adhesive and an copper ion migration resistant adhesive); and a film (specifically, it can be any one of a PI film, an MPI film, an LCP film, a TFP film and a PTFE film) after being added a colored filler can exhibit a corresponding color, such as black, red, green, blue, color, etc. The semi-cured high-frequency material layer having a color and the film both have a shielding effect on the circuit, which can prevent the internal circuit from being exposed, prevent the outsider from seeing the internal circuit from the outside, and play the role of concealing and protecting the circuit on the circuit board; meanwhile, it plays the role of masking defects for the circuit board or circuit with impurities or defects.

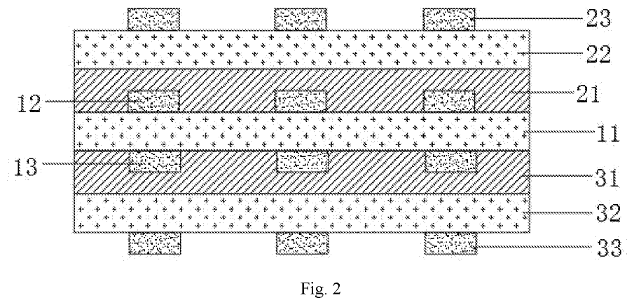

The embodiments of the present invention also provide a multi-layer flexible circuit board prepared by performing the above-mentioned method, as shown in FIGS. 1 and 2, comprising a double-sided FPC flexible board 1, several groups of upper novel material layer structures 2 laminated on the upper surface of the double-sided FPC flexible board 1, and several groups of lower novel material layer structures 3 laminated on the lower surface of the double-sided FPC flexible board 1, wherein the double-sided FPC flexible board 1 comprises a base film 11, a first upper circuit layer 12 arranged on the upper surface of the base film 11, and a first lower circuit layer 13 arranged on the lower surface of the base film 11; the upper novel material layer structure 2 comprises an upper semi-cured high-frequency material layer 21 arranged on the upper surface of the first upper circuit layer 12, an upper thin film 22 arranged on the upper surface of the upper semi-cured high-frequency material layer 21, and a second upper circuit layer 23 arranged on the upper surface of the upper thin film 22; and the lower novel material layer structure 3 comprises a lower semi-cured high-frequency material layer 31 arranged on the lower surface of the first lower circuit layer 13, a lower film 32 arranged on the lower surface of the lower semi-cured high-frequency material layer 31, and a second lower circuit layer 33 arranged on the lower surface of the lower film 32.

As shown in FIGS. 1 and 2, a group of upper novel material layer structures 2 is laminated on the upper surface of a double-sided FPC flexible board 1, and a group of lower novel material layer structures 3 is laminated on the lower surface to form a four-layer double-sided flexible circuit board; as shown in FIG. 4, two groups of upper novel material layer structures 2 are laminated on the upper surface of the double-sided FPC flexible board 1, and two groups of lower novel material layer structures 3 are laminated on the lower surface to form a six-layer double-sided flexible circuit board. Of course, more groups of novel material layer structures may be laminated on the upper and lower surfaces of the double-sided FPC flexible board to form a multi-layer flexible circuit board. It is also possible to form a three-layer double-sided flexible circuit board by hot-pressing only one group of upper novel material layer structures 2 on the upper surface of the double-sided FPC flexible board 1, as shown in FIG. 6, or hot-pressing only one group of lower novel material layer structures 3 on the lower surface of the double-sided FPC flexible board 1. Meanwhile, it is sufficient to form a protective layer 4 on the surface circuits of the double-sided FPC flexible board 1 which is not hot-pressed with a novel material layer structure; and the protective layer 4 can be a solder mask ink layer, or a combination of an adhesive layer layer and a PI film.

In this embodiment, the base film 11 is any one of a PI film, an MPI film, an LCP film, a TFP film, and a PTFE film; the upper film 22 is any one of a PI film, an MPI film, an LCP film, a TFP film, and a PTFE film; and the lower film 32 is any one of a PI film, an MPI film, an LCP film, a TFP film, and a PTFE film. The use of any one of PI film, MPI film, LCP film, TFP film and PTFE film as a substrate (the base film 11, the upper film 22 and the lower film 32) of the circuits formed on the double-sided FPC flexible board and a novel material layer structure is particularly suitable for the flexible circuit board. Especially, MPI film, LCP film, TFP film and PTFE film can not only improve the overall performance of the flexible circuit board, but also have high-frequency characteristics, which can greatly accelerate the transmission of high-frequency signals and achieve high-speed transmission of high-frequency signals, particularly suitable for novel 5G technology products.

In the present embodiment, the upper semi-cured high-frequency material layer 21 is an MPI film, an LCP film, a TFP film, a PTFE film, an LDK high-frequency functional adhesive, or a mixture of the LDK high-frequency functional adhesive with a copper ion migration resistant adhesive; and the lower semi-cured high-frequency material layer 31 is an MPI film, an LCP film, a TFP film, a PTFE film, an LDK high-frequency functional adhesive, or a mixture of the LDK high-frequency functional adhesive with a copper ion migration resistant adhesive. It can be seen from the above that MPI film, LCP film, TFP film, PTFE film and LDK high-frequency functional adhesive can accelerate the frequency and speed of signal transmission, transmit high-frequency signals and improve the signal transmission performance of the circuit board, which can not only improve the overall performance of the flexible circuit board, but also have high-frequency characteristics. They can greatly accelerate the transmission of high-frequency signals and achieve high-speed transmission of high-frequency signals, especially suitable for new 5G technology products. However, the mixture of LDK high-frequency functional adhesive and copper ion migration resistant adhesive has high-speed transmission high-frequency signals and copper ion migration resistant performance.

In this embodiment, at least one of the upper semi-cured high-frequency material layer 21 and the upper film 22 is a colored layer; and at least one of the lower semi-cured high-frequency material layer 31 and the lower film 32 is a colored layer. The colored layer can be specifically black, red, green, blue, color, etc.; and the colored layer plays the role of shielding, protection, masking and so on for the internal circuit.

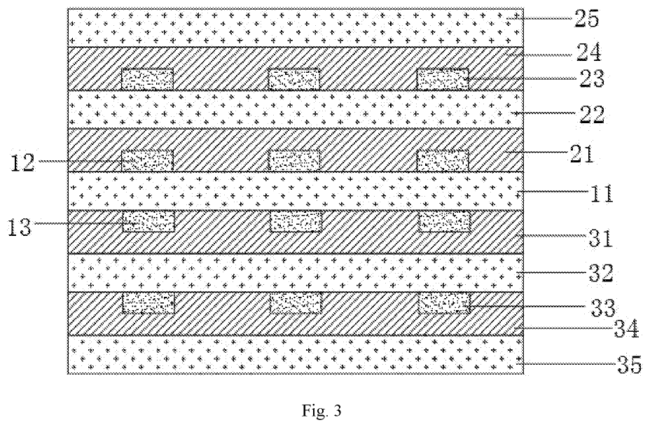

In the present embodiment, an upper protective layer is provided on the upper surface of the second upper circuit layer 23 of the outermost novel material layer structure 2 above the double-sided FPC flexible board 1; and a lower protective layer is provided on the lower surface of the second lower circuit layer 33 of the outermost novel material layer structure 3 below the double-sided FPC flexible board 1. Specifically, the upper protective layer is a solder mask ink layer or a combination of an adhesive layer and a PI film; and the lower protective layer is a solder mask ink layer or a combination of an adhesive layer and a PI film. As shown in FIGS. 3 and 5, the upper protective layer includes an upper adhesive layer 24 and an upper PI film 25; and the lower protective layer includes a lower adhesive layer 34 and a lower PI film 35. Meanwhile, as shown in FIG. 6, the upper surface of the second upper circuit layer 23 of the outermost novel material layer structure 2 above the double-sided FPC flexible board 1 is provided with an upper protective layer including an upper adhesive layer 24 and an upper PI film 25. The outermost circuit is protected by the upper protective layer and the lower protective layer to prevent oxidation, moisture absorption and corrosion of the circuit in the exposed atmosphere.

In this embodiment, compared with the traditional four-layer double-sided flexible circuit board, as shown in FIG. 3, two adhesive layers and two film layers are reduced only for the four-layer double-sided flexible circuit board with the improved upper novel material layer structure 2 and upper novel material layer structure 3, and the novel material layer structure of the product is greatly simplified; thus, the overall thickness of the multi-layer flexible circuit board is reduced, the overall product material cost is reduced, and the assembly space is optimized; and the product signal transmission speed is improved, the power consumption is reduced, and the moisture and heat resistance of the product is improved, so that the overall performance of the product is improved.

In the description above, only the preferred embodiments of the present invention has been described, and the technical scope of the present invention is not limited in any way. Therefore, other structures obtained by adopting the same or similar technical features as those of the above embodiments of the present invention are within the scope of the present invention.

1. A method for manufacturing a multi-layer flexible circuit board, characterized by comprising the steps of:
(1) manufacturing a double-sided FPC flexible board: applying a copper layer on upper and lower surfaces of a base film respectively, and forming a circuit on the copper layer to obtain a double-sided FPC flexible board;
(2) manufacturing at least one group of novel material layer structures;
(2.1) applying a copper layer on one surface of the film to form a single-sided board;
(2.2) applying a semi-cured high-frequency material layer on the other surface of the film of the single-sided board to obtain at least one group of novel material layer structures;
(3) thermoforming: hot-pressing at least one group of novel material layer structures on the circuits of the upper surface and/or the lower surface of the double-sided FPC flexible board; in the hot-pressing process, firstly, gradually increasing the hot-pressing temperature from 50° C.-100° C. to 380° C.-400° C. for 80 min -120 min; then, maintaining the hot-pressing temperature of 380° C.-400° C. for 60 min -90 min; finally, gradually decreasing the hot-pressing temperature from 380° C.-400° C. to 50° C.-100° C. for 30-60 min; wherein the hot pressing pressure is 400 psi -500 psi during the whole process;
after hot-pressing, the semi-cured high-frequency material layer on the novel material layer structure is integrated with the circuits on the double-sided FPC flexible board; in this step, after each group of the upper novel material layer structures is hot pressed, forming a circuit on the copper layer of the novel material layer structure; finally, a protective layer is formed on the circuits of an outermost novel material layer structure and/or on exposed circuits of the double-sided FPC flexible board so as to obtain a multi-layer flexible circuit board;
wherein the step (1) has no sequential order with the step (2).

2. The method for manufacturing a multi-layer flexible circuit board according to claim 1, characterized in that the step (2.2) specifically comprises the steps of:
(2.2.1) placing the single-sided board on a coater, and coating the film of the single-sided board with a layer of a synthetic liquid high-frequency material;
(2.2.2) delivering the single-sided board coated with the synthetic liquid high-frequency material into a tunnel oven, and successively passing it through a first-stage heating and baking zone, a second-stage heating and baking zone, a third-stage heating and baking zone, a fourth-stage heating and baking zone, a fifth-stage heating and baking zone and a sixth-stage heating and baking zone in the tunnel oven at a speed of 0.5-20 m/s for stepwise baking, wherein the synthetic liquid high-frequency material on the single-sided board becomes a semi-cured high-frequency material layer; the temperature range of the first-stage heating and baking zone is 60° C.-100° C.; the temperature range of the second-stage heating and baking zone is 100° C.-200° C.; the temperature range of the third-stage heating and baking zone is 200° C.-300° C.; the temperature range of the fourth-stage heating and baking zone is 300° C.-400° C.; the temperature range of the fifth-stage heating and baking zone is 400° C.-500° C.; the temperature range of the sixth-stage heating and baking zone is 60° C.-100° C.; and the length of each stage heating and baking zone is 2-6 m.

3. The method for manufacturing a multi-layer flexible circuit board according to claim 1, characterized in that in the step (1), the base film is any one of a PI film, an MPI film, an LCP film, a TFP film and a PTFE film; and in the step (2.1), the film is any one of a PI film, an MPI film, an LCP film, a TFP film and a PTFE film.

4. The method for manufacturing a multi-layer flexible circuit board according to claim 1, characterized in that in the step (2.2), the semi-cured high-frequency material layer is an MPI film, an LCP film, a TFP film, a PTFE film, an LDK high-frequency functional adhesive, or a mixture of the LDK high-frequency functional adhesive with a copper ion migration resistant adhesive.

5. The method for manufacturing a multi-layer flexible circuit board according to claim 4, characterized in that the LDK high-frequency functional adhesive is obtained by adding Teflon or LCP material to an AD adhesive; and the copper ion migration resistant paste is obtained by adding a copper ion scavenger to the AD adhesive, followed by high purification.

6. The method for manufacturing a multi-layer flexible circuit board according to claim 1, characterized in that in the step (2.2), a colored filler is added to at least one of the semi-cured high-frequency material layer and the film.

7. A multi-layer flexible circuit board prepared by performing the method of any one of claims 1 to 6, characterized by comprising a double-sided FPC flexible board, several groups of upper novel material layer structures laminated on the upper surface of the double-sided FPC flexible board, and several groups of lower novel material layer structures laminated on the lower surface of the double-sided FPC flexible board, wherein the double-sided FPC flexible board comprises a base film, a first upper circuit layer arranged on the upper surface of the base film, and a first lower circuit layer arranged on the lower surface of the base film; the upper novel material layer structure comprises an upper semi-cured high-frequency material layer arranged on the upper surface of the first upper circuit layer, an upper film arranged on the upper surface of the upper semi-cured high-frequency material layer, and a second upper circuit layer arranged on the upper surface of the upper film; and the lower novel material layer structure comprises a lower semi-cured high-frequency material layer arranged on the lower surface of the first lower circuit layer, a lower film arranged on the lower surface of the lower semi-cured high-frequency material layer, and a second lower circuit layer arranged on the lower surface of the lower film.

8. The multi-layer flexible circuit board according to claim 7, characterized in that the base film is any one of a PI film, an MPI film, an LCP film, a TFP film and a PTFE film; the upper film is any one of a PI film, an MPI film, an LCP film, a TFP film and a PTFE film; and the lower film is any one of a PI film, an MPI film, an LCP film, a TFP film and a PTFE film.

9. The multi-layer flexible circuit board according to claim 7, characterized in that the upper semi-cured high-frequency material layer is an MPI film, an LCP film, a TFP film, a PTFE film, an LDK high-frequency functional adhesive, or a mixture of the LDK high-frequency functional adhesive with a copper ion migration resistant adhesive;
and the lower semi-cured high-frequency material layer is an MPI film, an LCP film, a TFP film, a PTFE film, an LDK high-frequency functional adhesive, or a mixture of the LDK high-frequency functional adhesive with a copper ion migration resistant adhesive.

10. The multi-layer flexible circuit board according to claim 7, characterized in that at least one of the upper half-cured high-frequency material layer and the upper film is a colored layer; and at least one of the lower half-cured high-frequency material layer and the lower film is a colored layer.

11. The multi-layer flexible circuit board according to claim 7, characterized in that an upper protective layer is provided on the upper surface of the second upper circuit layer of the outermost novel material layer structure above the double-sided FPC flexible board; and a lower protective layer is provided on the lower surface of the second lower circuit layer of the outermost lower novel material layer structure below the double-sided FPC flexible board.

12. The multi-layer flexible circuit board according to claim 11, characterized in that the upper protective layer is a solder mask ink layer or a combination of an adhesive layer and a PI film; and the lower protective layer is a solder mask ink layer or a combination of an adhesive layer and a PI film.
